(19) United States
(12) Patent Application Publication
(10) Pub. No.: US 2005/0087873 A1
(43) Pub. Date: Apr. 28, 2005

(54) Method and structure for selective surface passivation

(76) Inventors: Chih-I Wu, Hillsboro, OR (US); Jihperng Leu, Portland, OR (US)

Correspondence Address: Michael A. Bernadicou;BLAKELY, SOKOLOFF, TAYLOR & ZAFMAN LLP, Seventh Floor, 12400 Wilshire Boulevard, Los Angeles, CA, 90025, US

(21) Appl. No.: 10/948,046

(22) Filed: Sep. 22, 2004

Related U.S. Application Data
(62) Division of application No. 10/335,033, filed on Dec. 31, 2002.

(51) Int. Cl. H01L 21/4763; H01L 21/44; H01L 23/52; H01L 29/40

(52) U.S. Cl. 257/751; 438/687; 438/643; 438/648; 438/623; 257/629; 257/642

(57) ABSTRACT

Method and structure for passivating conductive material are disclosed. Atomic layer deposition of a thin passivation layer such as titanium nitride upon a conductive layer comprising a material such as copper, in the presence of a dielectric material not conductive to surface reaction with gaseous precursors used in the deposition schema, facilitates highly selective and accurate passivation which may improve electromigration performance, minimize leakage current to other conductive layers, and streamline process steps.

### BACKGROUND OF THE INVENTION

As critical dimensions shrink and current control remains a significant issue in microelectronic structure manufacturing, accurate deposition of passivation or barrier materials to provide step coverage using conventional techniques such as physical vapor deposition (PVD) becomes increasingly challenged and alternative technologies are needed. Passivation layer deposition may be required at complex surfaces which comprise passivation target regions interspersed among regions where a passivation layer is not needed or desired. For example, upon a surface comprising an exposed surface of a metal interconnect line which is surrounded by exposed surfaces comprising interlayer dielectric materials, it may not be desirable to passivate the entire layer in whole, because such blanket passivation may be more likely to facilitate current leakage to adjacent interconnect lines or devices. Such a scenario is illustrated in FIG. 1.

Referring to FIG. 1, an interconnect structure is shown comprising a first dielectric layer (102) formed between a substrate layer (100) and a second conductive layer (108), the first dielectric layer (102) being crossed by a conductive layer (104). The depicted passivation or barrier layer (107), positioned between the conductive layer (104) and the second dielectric layer (108), also extends across portions (110, 112) of the first dielectric layer (102) due to the limitations of modem conventional techniques, such as chemical vapor deposition (CVD) or PVD, for depositing thin barrier materials. As illustrated in FIG. 1, portions of the barrier layer (107) extending beyond the conductive layer (104) may facilitate detrimental current leakage to and from other adjacent conductive layers (not shown) by providing possible conduction pathways (136, 137), depending upon the materials selected for the barrier layer (107). In scenarios such as the one depicted, the extra coverage of the passivation layer (107) beyond the conductive layer (104) surface is nonideal. Another weakness of conventional barrier deposition techniques such as CVD and PVD is coverage and uniformity. With such techniques, extra material may be deposited to ensure coverage as close to 100% of the desired surface, and adequate thickness of deposited barrier material on surfaces such as trench sidewalls or out-of-plane curved surfaces, which may have less direct exposure to the deposition source, may be questionable depending upon the particular modality.

Given the common use of interconnect materials such as copper which are known to diffuse or electromigrate into other commonly adjacent materials and potentially fatally contaminate adjacent devices or transistors, along with the inadequacies of conventional blanket deposition techniques as applied in passivation scenarios, accurate and reliable passivation remains an issue.

### BRIEF DESCRIPTION OF THE DRAWINGS

The present invention is illustrated by way of example and is not limited in the figures of the accompanying drawings, in which like references indicate similar elements. Features shown in the drawings are not intended to be drawn to scale, nor are they intended to be shown in precise positional relationship.

FIG. 1 depicts a cross-sectional view of a conventional interconnect-related structure having a blanket-deposited passivation layer.

FIG. 2 depicts a cross-sectional view of one embodiment of the inventive interconnect-related structure having a passivation layer selectively deposited upon a surface of the depicted conductive layer.

FIGS. 3A-3G depict cross-sectional views of various phases of an embodiment of the present invention wherein a passivation layer is selectively deposited upon a surface of a conductive layer.

### DETAILED DESCRIPTION

In the following detailed description of embodiments of the invention, reference is made to the accompanying drawings in which like references indicate similar elements. The illustrative embodiments described herein are disclosed in sufficient detail to enable those skilled in the art to practice the invention. The following detailed description is therefore not to be taken in a limiting sense, and the scope of the invention is defined only by the appended claims.

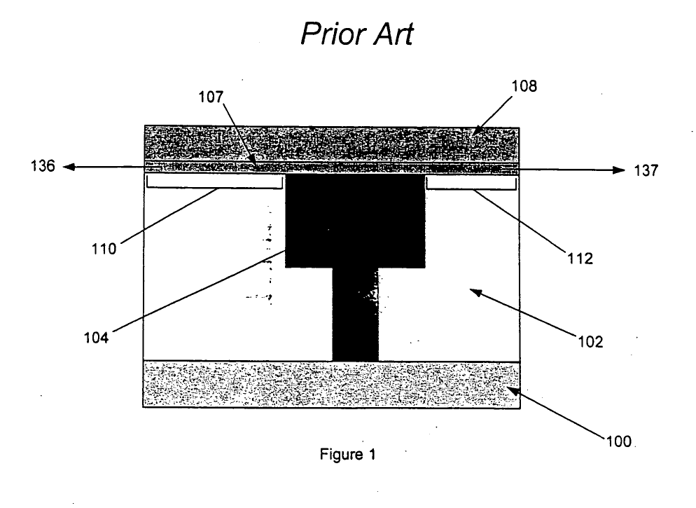

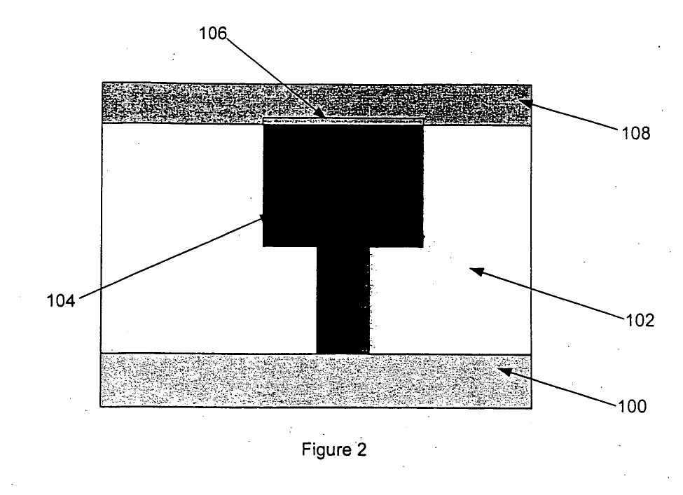

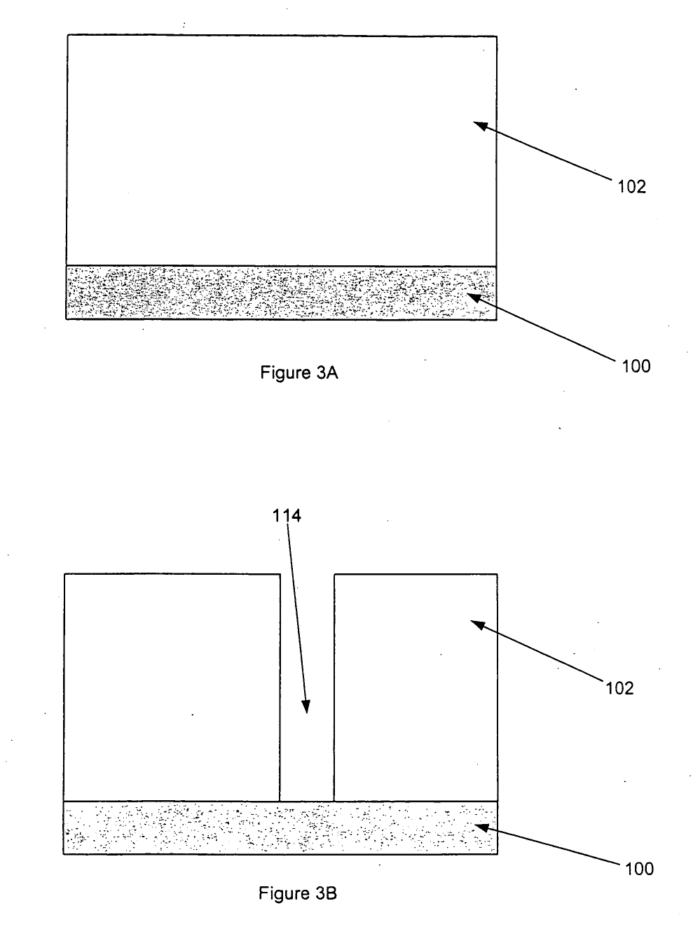

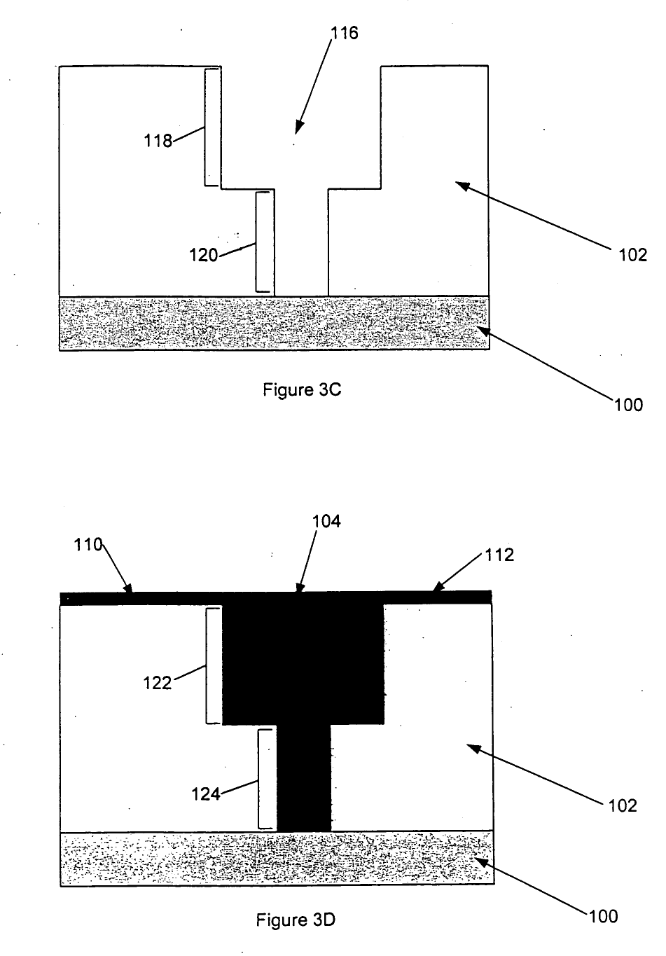

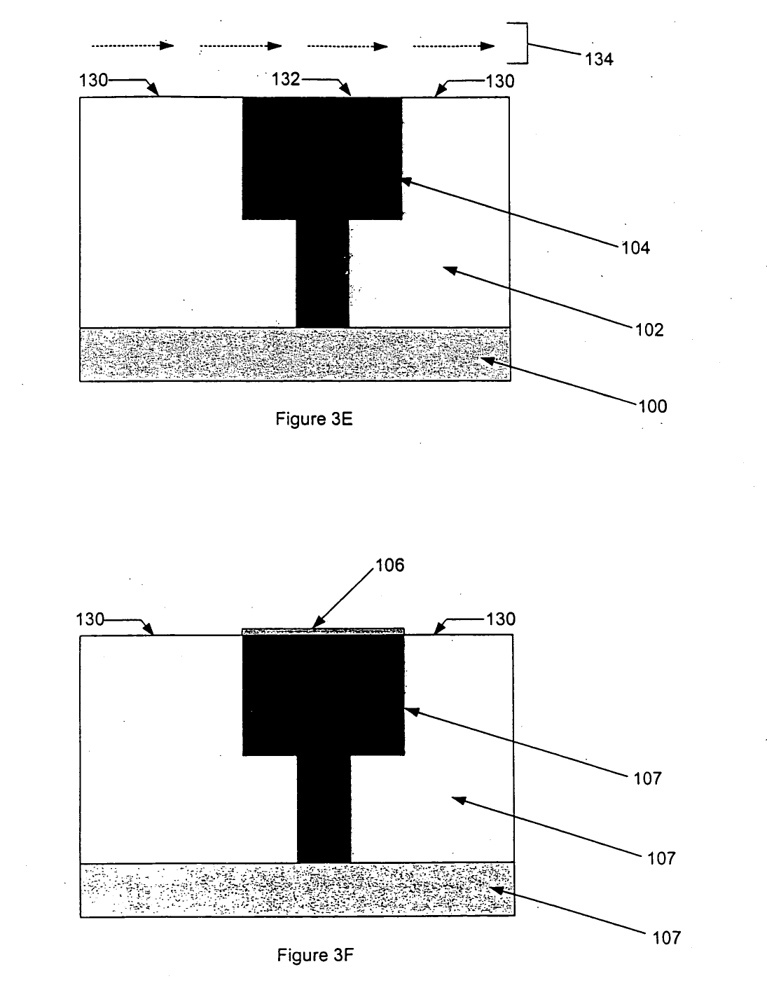

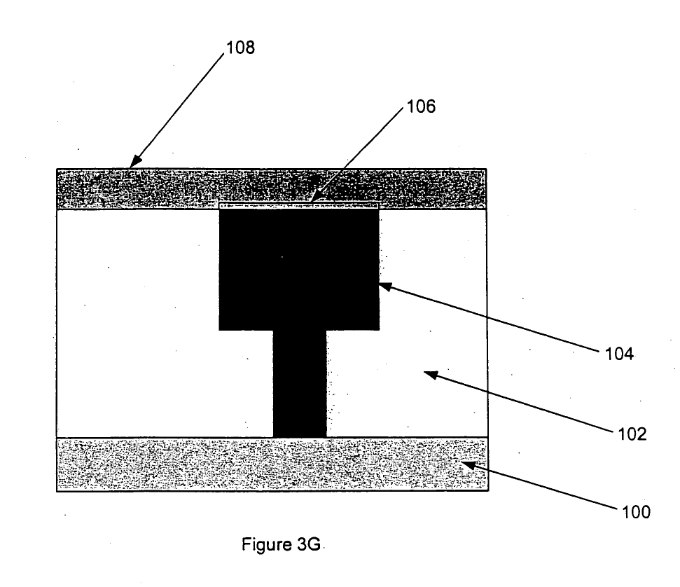

Referring to FIG. 1, a microelectronic structure is depicted having a passivation layer (107) which has been blanket deposited across not only the exposed surface of the associated conductive layer (104), but also across exposed surfaces (110, 112) of the adjacent first dielectric layer (102). Per the discussion above, such a structure can be nonideal, leading to possible current leakage, among other things. Referring to FIG. 2, a structure formed in accordance with the present invention is depicted, such structure having a passivation layer (106) selectively deposited only across the exposed surface of the conductive material (104), at an appropriate time during the pertinent integration process. FIGS. 3A-3G illustrate an embodiment of such a process in further detail.

Referring to FIG. 3A, a substrate layer (100) is depicted, upon which a first dielectric layer (102) has been formed. The substrate (100) may be any surface generated when making an integrated circuit, upon which a conductive layer may be formed. Substrate (100) thus may comprise, for example, active and passive devices that are formed on a silicon wafer, such as transistors, capacitors, resistors, diffused junctions, gate electrodes, local interconnects, etcetera. Substrate (100) may also comprise insulating materials (e.g., silicon dioxide, either undoped or doped with phosphorus or boron and phosphorus; silicon nitride; silicon oxynitride; or a polymer) that separate active and passive devices from the conductive layer or layers that are formed adjacent them, and may comprise other previously formed conductive layers.

Referring back to FIG. 2, the passivation layer (106) is selectively positioned adjacent the conductive layer (104), while the nearby interface between the first dielectric layer (102) and the second dielectric layer (108) is not interrupted by passivation material. The passivation layer (106) preferably is selectively deposited upon the conductive layer (104) and not upon the first dielectric layer (102) using sequential exposure of gaseous precursors selected to react with the material comprising the conductive layer (104) without substantially reacting to the material comprising the first dielectric layer (102). Sequential precursor exposure for selective deposition of atomic layers of material, variations of which may be referred to as “atomic layer deposition”, has been applied to facilitate the formation of passivation materials such as transition metal nitrides upon substrate materials such as silicon, silicon dioxide, and glass. To the contrary, the inventive integrations described herein apply sequential precursor exposure to avoid deposition of passivation materials upon dielectric materials comprising the first dielectric layer (102), while facilitating deposition of passivation materials upon adjacent conductive layer surfaces. Referring again to FIG. 3A, the first dielectric layer (102) therefore preferably comprises a dielectric material which does not nucleate or chemisorb subsequently introduced gaseous precursors used to form a passivation layer such as the passivation layer (106) depicted in FIG. 3F. In the preferred embodiment, the first dielectric layer comprises a dielectric material lacking available negative polar groups reactive with precursors comprising ammonia and titanium tetrachloride, such as polyarylene-based polymer dielectric materials, and carbon doped oxides, preferably formed using conventional techniques such as spin-on, chemical vapor deposition, and physical vapor deposition. For example, the polyarylene-based polymers sold under the names “SiLK™” and “GX-3™” do not substantially nucleate or chemisorb ammonia or titanium tetrachloride precursors, which may be sequentially introduced to selectively deposit a titanium nitride passivation layer upon a copper conductive layer surface. Porous and nonporous carbon doped oxide (“CDO”) materials, having the molecular structure Six Oy Rz, in which “R” is an alkyl or aryl group, the CDO preferably comprising between about 5 and about 50 atom % carbon, and more preferably, about 15 atom % carbon, also do not substantially nucleate or chemisorb ammonia or titanium tetrachloride precursors. Suitable CDO materials for the first dielectric layer (102) include but are not limited to a CVD-deposited CDO materials such as those sold under the trade names “Black Diamond™” and “Coral™”, distributed by Applied Materials Corporation and Novellus Corporation, respectively, as well as commercially available electron-beam-cured CVD-deposited CDO materials.

Referring to FIG. 3B, a structure similar to that of FIG. 3A is shown with the exception that a trench (114) has been formed through the first dielectric layer (102) using conventional techniques, such as patterning and etching lithography techniques, as are well known in the art. As shown in FIG. 3C, an enlarged trench (116) is formed using similar conventional techniques, the enlarged trench having a relatively narrow via portion (120) and a relative wide line portion (118), as is convention, for example, in dual damascene electroplating of conductive materials such as copper. As would be apparent to one skilled in the art, the trench (116) need not have a dual damascene shape or extend to the substrate layer (100) as shown in the depicted embodiment.

Referring to FIG. 3D, the enlarged trench (116) of the previous illustration has been filled with a conductive material, such as copper, using, for example, conventional electroplating techniques. The trench may be overfilled, as depicted, to leave conductive layer portions (110, 112) outside of the previously defined trench. Such portions (110, 112) may be removed with techniques such as chemical mechanical polishing (CMP), to leave a substantially planar surface comprising an exposed conductive layer surface (132) and an exposed first dielectric layer surface (130), as shown in FIG. 3E. These surfaces (130, 132) need not be substantially within the same plane, and indeed, often they will be positioned in different planes and/or comprise nonplanar exposed surfaces. For example, the conductive layer exposed surface (132) may be recessed within the first dielectric layer, and positioned in a plane below that of the depicted first dielectric layer exposed surface (130). Similarly, the exposed surfaces (130, 132) may not be uniformly planar, and ridges, trenches, etc may define such surfaces. Conventional “subtractive metallization” techniques, wherein a layer of conductive material is deposited and then partially removed to leave behind a desired discrete conductive layer, may also be used to form conductive layers, as would be apparent to one skilled in the art.

A series of dashed arrows (134) positioned above the exposed surfaces (130, 132) in FIG. 3E represents a series of sequential precursor gas exposures selected to react with the surface chemistry of the conductive layer exposed surface, and not with the first dielectric layer exposed surface, to produce a selectively deposited barrier or passivation layer (106), as shown in FIG. 3F. Per the above discussion, key to this invention are pairings of dielectric material, gaseous precursors, and conductive layer material conducive to such selective reaction and concomitant deposition. In one embodiment a titanium nitride barrier layer (106) is selectively deposited upon an exposed surface of a copper conductive layer (104) and not upon the exposed surface of the first dielectric layer (102), which preferably comprises one of the aforementioned materials not substantially nucleating or chemisorbing ammonia and titanium tetrachloride gaseous precursors, such precursors being selected to deposit titanium nitride upon the copper conductive layer exposed surface as a result of sequential and distinct saturative surface reactions. In between the distinct exposures of gaseous ammonia and gaseous titanium tetrachloride, timed at a minimum of about I second to allow for full saturative surface reaction, exposures of inert gas, such as argon, are used to purge the exposed surfaces of prior gaseous precursors or airborne surface reaction byproducts. In other words, each cycle comprises a first saturation surface reaction, a purging, and a second saturation surface reaction building upon the results of the first saturation surface reaction, each cycle resulting in a thin passivation layer (106) having atomic-level thickness uniformity due to the saturative, self-limiting nature of the surface chemistry involved. As noted above, the deposition of monolayers of atoms or molecules with sequential saturative reactions as described herein may be categorized as a variation of “atomic layer deposition”, which has been used for depositing thin, controllable layers of material upon surfaces such as glasses or oxides. The exposed surface of the preferred copper conductive layer (104) preferably is maintained at a temperature between about 370 and 390 degrees Celsius while sequential pulses or ammonia and titanium tetrachloride are introduced at a frequency of about 1 second, separated by pulses of argon gas. Approximately 0.005 nanometers of titanium nitride are grown per cycle, meaning that an overall barrier layer thickness of 1-2 nanometers requires a significant quantity of cycles and time.

Referring to FIG. 3G, subsequent to formation of the passivation layer (106), a second dielectric layer (108) may then be deposited over the exposed portions of the passivation layer (106) and first dielectric layer (102). The second dielectric layer (108) may comprise any material that may insulate one conductive layer from another without incompatibility with the adjacent passivation layer (106) and first dielectric layer (102). Suitable materials include but are not limited to silicon dioxide (either undoped or doped with phosphorus or boron and phosphorus); silicon nitride; silicon oxy-nitride; porous oxide; an organic containing silicon oxide; carbon doped oxides, as further described above, with a low dielectric constant: preferably less than about 3.5 and more preferably between about 1.5 and about 3.0; organic polymers such as polyimides, parylene, polyarylethers, organosilicates, polynaphthalenes, polyquinolines, and copolymers thereof. Examples of other types of materials that may be used to form the second dielectric layer (108) include aerogel, xerogel, and spin-on-glass (“SOG”). In addition, the second dielectric layer (108) may comprise either hydrogen silsesquioxane (“HSQ”), methyl silsesquioxane (“MSQ”), which may be coated onto the surface of a semiconductor wafer using a conventional spin coating process. Although spin coating may be a preferred way to form the second dielectric layer (108) for some materials, for others chemical vapor deposition, plasma enhanced chemical vapor deposition, a SolGel process, or foaming techniques may be preferred. Other suitable second dielectric layer (108) materials, such as those known as “zeolites”, have naturally occurring interconnected pores. While the term “zeolite” has been used in reference to many highly-ordered mesoporous materials, several zeolites are known as dielectric materials, such as mesoporous silica and aluminosilicate zeolite materials. Zeolite materials may be synthesized by an aerogel or xerogel process, spin-coated into place, or deposited using chemical vapor deposition to form a voided structure upon deposition. In the case of spin coating or other deposition methods, solvent may need to be removed using evaporative techniques familiar to those skilled in the art.

Thus, a novel passivation solution is disclosed. Although the invention is described herein with reference to specific embodiments, many modifications therein will readily occur to those of ordinary skill in the art. Accordingly, all such variations and modifications are included within the intended scope of the invention as defined by the following claims.

1. A method to form a microelectronic structure comprising:
forming a dielectric layer adjacent a substrate layer, the dielectric layer having an exposed surface after said forming;
forming a conductive layer at least partially across the dielectric layer having an exposed surface adjacent the exposed surface of the dielectric layer;
heating the exposed surface of the conductive layer to a temperature above 300 degrees Celsius;
sequentially exposing both the exposed surface of the dielectric layer, and the exposed surface of the conductive layer to at least two gaseous precursors to deposit a barrier layer only upon the exposed surface of the conductive layer.

2. The method of claim 1 wherein the dielectric layer comprises a carbon doped oxide.

3. The method of claim 1 wherein the dielectric layer comprises a polymer.

4. The method of claim 3 wherein the polymer comprises a polyarylene-based polymer.

5. The method of claim 4 wherein the polymer comprises a polyarylene-based polymer from the group consisting of SiLK™ and GX-3™.

6. The method of claim 1 wherein the dielectric layer comprises a material lacking available negative polar groups reactive with metals.

7. The method of claim 1 wherein the conductive layer comprises copper.

8. The method of claim 1 wherein heating comprises raising the temperature of the exposed surface to between about 370 and about 390 degrees Celsius.

9. The method of claim 1 wherein the at least two gaseous precursors comprise ammonia.

10. The method of claim 1 wherein the at least two gaseous precursors comprise titanium tetrachloride.

11. The method of claim 1 wherein the barrier layer comprises titanium nitride.

12. The method of claim 1 wherein sequentially exposing comprises exposing both the exposed surface of the dielectric layer, and the exposed surface of the conductive layer to a first gaseous precursor to facilitate a first saturation surface reaction, and the exposed surface of the conductive layer to a second gaseous precursor to facilitate a second saturation surface reaction, the first and second saturation surface reactions not occurring upon the exposed surface of the dielectric layer.

13. A microelectronic structure comprising:
a dielectric layer;
a conductive layer crossing at least a portion of the dielectric layer, the dielectric layer and conductive layer defining an interconnect surface comprising a conductive layer exposed surface and a dielectric layer exposed surface;
a barrier layer disposed only upon the conductive layer exposed surface, the barrier layer having atomic-level thickness uniformity.

14. The microelectronic structure of claim 13 wherein the passivation layer is less than about 2 nanometers in thickness.

15. The microelectronic structure of claim 13 wherein the dielectric layer comprises a carbon doped oxide.

16. The microelectronic structure of claim 13 wherein the dielectric layer comprises a polymer.

17. The microelectronic structure of claim 13 wherein the polymer comprises a polyarylene-based polymer.

18. The microelectronic structure of claim 17 wherein the polymer comprises a polyarylene-based polymer from the group consisting of SiLK™ and GX-3™.

19. The microelectronic structure of claim 13 wherein the dielectric layer comprises a material lacking available negative polar groups reactive with metals.

20. The microelectronic structure of claim 13 wherein the conductive layer comprises copper.

21. The microelectronic structure of claim 13 wherein the barrier layer comprises titanium nitride.

22. The microelectronic structure of claim 13 wherein the barrier layer is formed by sequentially exposing both the expose surface of the dielectric layer, and the exposed surface of the conductive layer to a first gaseous precusor to facilitate a first saturation surface reaction at the exposed surface of the conductive layer, and subsequently exposing both the exposed surface of the dielectric layer, and the exposed surface of the conductive layer to a second gaseous precursor to facilitate a second saturation surface reaction at the exposed surface of the conductive layer, the first and second saturation surface reactions not occurring upon the exposed surface of the dielectric layer.

23. The microelectronic structure of claim 22 wherein the barrier layer comprises titanium nitride, wherein the first gaseous precursor comprises titanium tetrachloriede, and wherein the second gaseous precursor comprises ammonia.
